(19) United States
(12) Patent Application Publication
(10) Pub. No.: US 2014/0008260 A1
(43) Pub. Date: Jan. 9, 2014

(54) Case and Protective Film for Mobile Electronic Device

(71) Applicant: Tutomu Kanaya, Osaka (JP)

(72) Inventor: Tutomu Kanaya, Osaka (JP)

(21) Appl. No.: 13/499,729

(22) PCT Filed: Nov. 25, 2011
(86) PCT No.: PCT/JP11/06587

§ 371 Date: Apr. 2, 2012

(30) Foreign Application Priority Data
Mar. 11, 2011 (JP) 2011-001343
Jun. 28, 2011 (JP) 2011-003670

(51) Int. Cl. H05K 5/02

(52) U.S. Cl. CPC H05K 5/0252
USPC 206/459.5; 428/195.1

(57) ABSTRACT

The invention provides a case and a protective film for a mobile electronic device with which decoration can be easily replaced and simply enjoyed to suit individual tastes by using characters and figure logos of the device when the case or the protective film is attached to the device. The case or the protective film having a shape conforming to an outer shape of a back face and side faces of the device is made of a translucent material, and figures or characters are applied on the outer or the inner surface side of the case or the protective film covering the back face of the device so that when the case or the protective film is attached to the device, a logo mark and a logo character of the device can be seen through, and one motif is created integrally with the logo mark or the logo character.

### TECHNICAL FIELD

The present invention relates to a technology for a case and a protective film for mobile electronic devices including a mobile phone, a mobile computer terminal, a mobile game machine, an electronic dictionary, an electronic organizer and the like.

### BACKGROUND ART

A case fitted and integrated with a device main body has been used for protecting the surface of the mobile electronic devices. Some cases have visually recognizable patterns from the outer surface side. Decoration of the mobile electronic device can be freely changed by using the patterns depending on a user's taste.

That is, with the patterns on the case, the decoration on the mobile electronic device can be easily replaced and simply enjoyed, and the surface of the mobile electronic device is protected from damage (See Patent Document 1, for example).

On the other hand, name logos of mobile electronic devices represented, for example, by a famous mobile phone, iPhone (registered trademark), and figure logos represented by a design of an apple, a brand of Apple, are known. Since a case hides the logo on the mobile electronic device, many users of mobile electronic devices of such popular brands refuse the attachment of a case.

Thus, in order to prevent the case from hiding the logo, a case and a protective film of a transparent material are used.

[Patent Document 1] JP,3106279,U

### DISCLOSURE OF THE INVENTION

### Problems to be Solved by the Invention

Users of mobile electronic devices want to enjoy the decoration of the main body easily by attaching the case or protective film with patterns on the mobile electronic device, but some users refuse the attachment since they do not want the character or figure logos on the mobile electronic devices hidden.

In view of such circumstances, the present invention has an object to provide a case and a protective film for a mobile electronic device with which decoration can be easily replaced and simply enjoyed to suit individual tastes by using characters and figure logos of the mobile electronic device when the case or the protective film is attached to the mobile electronic device.

### Means to Solve the Objects

In order to achieve the above object, a case for a mobile electronic device of the present invention having a shape conforming to an outer shape of a back face and side faces of the mobile electronic device is made of a translucent material, and figures or characters are applied on the outer surface side or the inner surface side of the case covering the back face of the mobile electronic device so that when the case is attached to the mobile electronic device, a logo mark and a logo, character of the device can be seen through, and one motif can be created integrally with at least one of the logo mark and the logo character.

According to this configuration, decoration to suit individual tastes can be easily replaced and simply enjoyed by using the character and figure logos of the mobile electronic device.

Figures or characters attached on the inner surface side of the case covering the back face of the mobile electronic device can prevent damage on the attached figures or characters more easily.

In this description, the mobile electronic device refers to a mobile phone, a mobile digital music player, a mobile computer including a tablet computer, a laptop computer and the like, a mobile game machine, an electronic dictionary or an electronic organizer.

A protective film for a mobile electronic device of the present invention covering the outer shape of a back face and side faces of the mobile electronic device is made of a translucent material, and figures or characters are applied on the outer surface side or the inner surface side of the protective film covering the back face of the mobile electronic device so that when the protective film is attached to the mobile electronic device, a logo mark and a logo character of the device can be seen through, and one motif can be created integrally with at least one of the logo mark and the logo character. According to this configuration, decoration to suit one's taste can be easily replaced and simply enjoyed by using the character and figure logos of the mobile electronic device.

Application of figures or characters on the inner surface side of the protective film covering the back face of the mobile electronic device can prevent damage on the attached figures or characters more easily.

The figures or characters on the case or protective film are preferably provided on the outer surface or inner surface of the case by mirror printing.

The character or figure logos on the mobile electronic device are formed by mirror printing in many cases, and if the figures or characters on the case or protective film are also formed by mirror printing, the character or figure logos on the mobile electronic device are integrated with those on the case or protective film, and one motif can be created easily.

The case is preferably formed of a transparent synthetic resin sheet. Sheets made of polycarbonate, polypropylene, polyethylene-terephthalate, polyvinyl chloride and the like can be suitably used as the synthetic resin sheet.

The figure on the case or protective film is preferably any one of a vehicle carrying the logo mark of the mobile electronic device, a building having the logo mark of the mobile electronic device as contents of a signboard on the roof, a button of a keyboard using the logo mark of the mobile electronic device, a container or package of the logo mark of the mobile electronic device, and an animal or a plant in contact with the logo mark of the mobile electronic device.

### Effects of the Invention

According to the present invention, by attaching the case or protective film on the mobile electronic device, the decoration can be easily replaced and simply enjoyed to suit one's taste by using the character or figure logo of the mobile electronic device, which is an advantage.

### BRIEF DESCRIPTION OF THE DRAWINGS

FIG. 1 is an explanatory perspective view of a case for a mobile electronic device of the present invention and the mobile electronic device.

FIG. 2 is an explanatory view of a logo on the back side surface of the mobile electronic device.

FIG. 3 is an explanatory diagram of decoration on the case for the mobile electronic device of Embodiment 1.

FIG. 4 is an explanatory diagram of decoration on the case for the mobile electronic device of Embodiment 2.

FIG. 5 is an explanatory diagram of decoration on the case for the mobile electronic device of Embodiment 3.

FIG. 6 is an explanatory diagram of decoration on the case for the mobile electronic device of Embodiment 4.

FIG. 7 is an explanatory diagram of decoration on the case for the mobile electronic device of Embodiment 5.

FIG. 8 is an explanatory diagram of decoration on the case for the mobile electronic device of Embodiment 6.

FIG. 9 is an explanatory perspective view of a protective film for a mobile electronic device of the present invention and the mobile electronic device.

### BEST MODE FOR CARRYING OUT THE INVENTION

Hereinafter, an embodiment of the present invention will be described with reference to the accompanying drawings. The present invention is not limited to the illustrated construction. The present invention can be variously changed in design.

### Embodiment 1

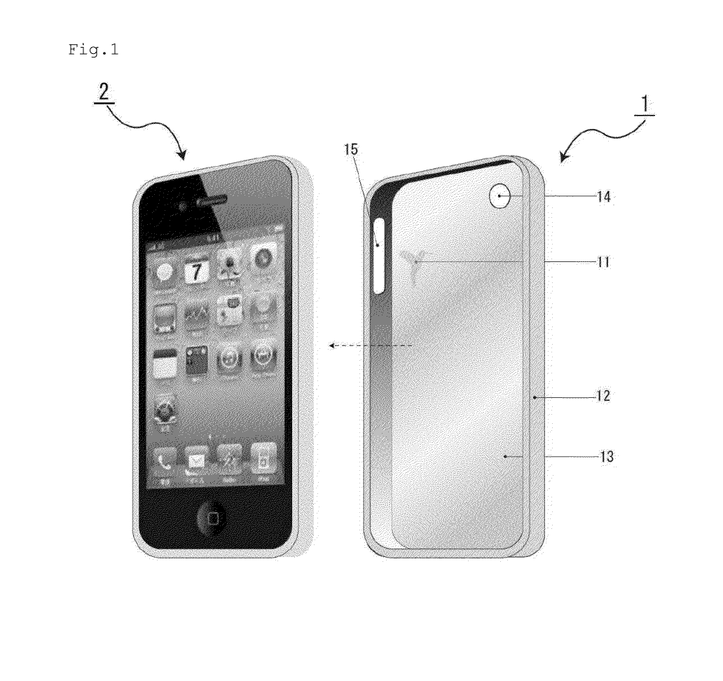

FIG. 1 is an explanatory perspective view of a case for a mobile electronic device of the present invention and the mobile electronic device. A mobile electronic device 2 is a mobile phone having a touch-panel front face. In a main-body fitted type case 1, a portion from a back face to side faces of the mobile electronic device 2 is protected. A frame 12 and the back face 13 of the case 1 use a polycarbonate clear material. A hole 14 for a camera lens corresponding to a camera lens position of the mobile electronic device 2 is provided in the back face 13. A hole 15 for an operation switch corresponding to an operation switch position of the mobile electronic device 2 is also provided in the frame 12.

A pattern 11 is applied on the back face 13 of the case 1 by mirror printing in silver color.

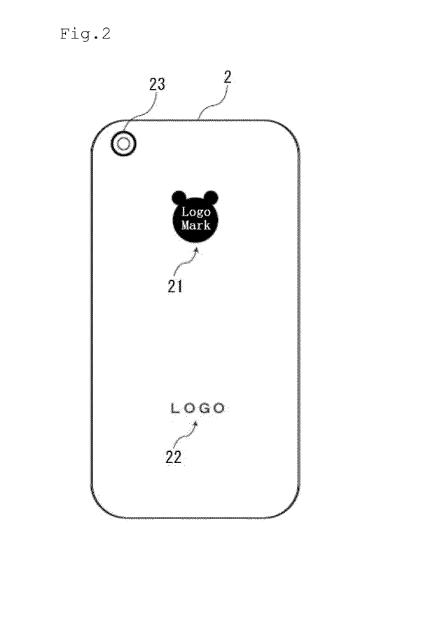

FIG. 2 illustrates a logo on the surface on the backside of the mobile electronic device 2. In the example in FIG. 2, a figure logo mark 21 slightly above the center and a character logo 22 below the center are given on the surface of the back side of the mobile electronic device 2 by mirror printing in silver color. Reference numeral 23 denotes a camera lens of the mobile electronic device 2.

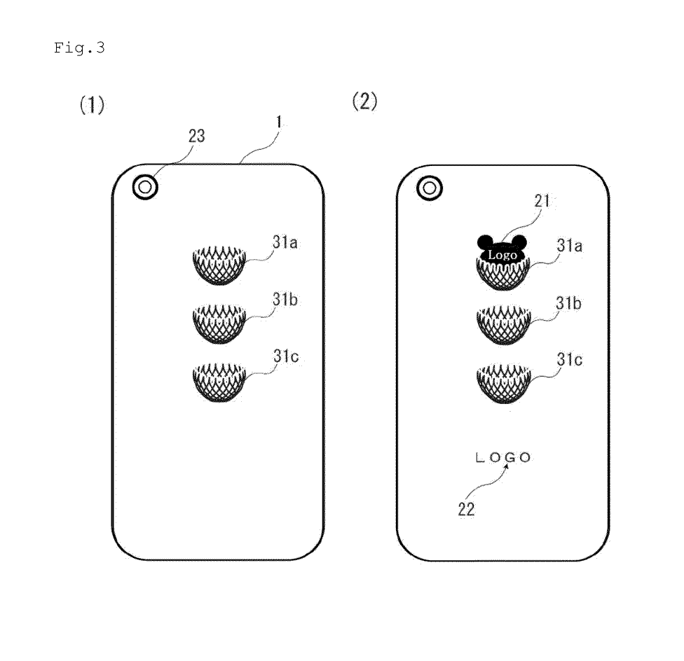

FIG. 3 illustrates decoration applied on the case for a mobile electronic device in Example 1. FIG. 3(1) illustrates a pattern applied on the case 1. FIG. 3(2) illustrates a case attached to the main body of the mobile electronic device 2. When three patterns (31a to 31c), each having a meshed semispherical basket shape, on the case 1 are overlapped with the logo mark 21, the logo mark 21 looks to be decorated by the semispherical basket. A user can feel as if a part of the logo mark 21 is clothed. That is, by applying the figure of the container or package of the logo mark of the mobile electronic device on the case at a predetermined position and with a predetermined shape or size, a motif that the logo mark is clothed is created for users.

### Embodiment 2

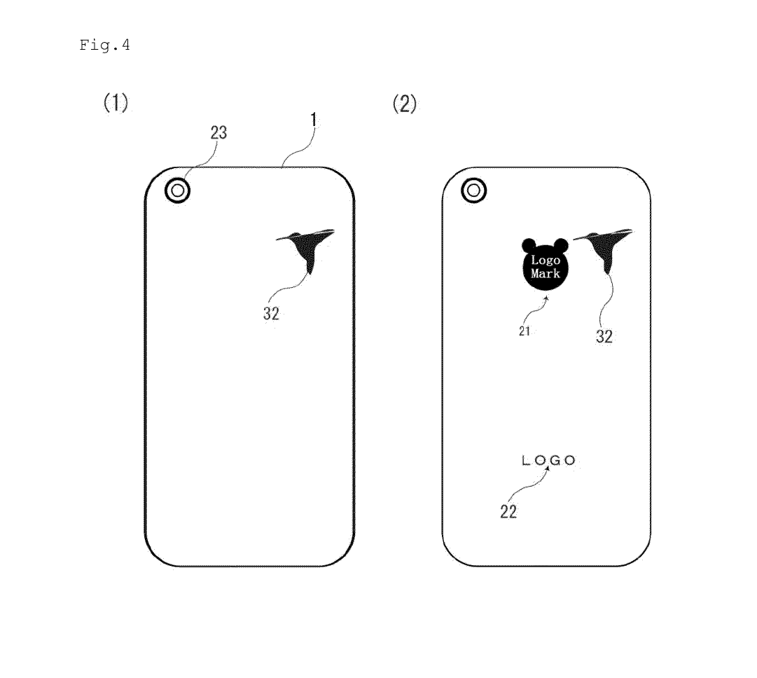

FIG. 4 illustrates decoration applied on the case for a mobile electronic device of Example 2. FIG. 4(1) is a pattern applied on the case 1, and FIG. 4(2) illustrates the case attached to the main body of the mobile electronic device 2. When a bird pattern 32 on the case 1 is overlapped with the logo mark 21, the logo mark 21 looks as if it is pecked by beaks of the bird. That is, by applying the figure of an animal or a plant in contact with the logo mark of the mobile electronic device on the case at a predetermined position and with a predetermined shape or size, a motif that the logo mark coexists with the animal or the plant is created for users.

### Embodiment 3

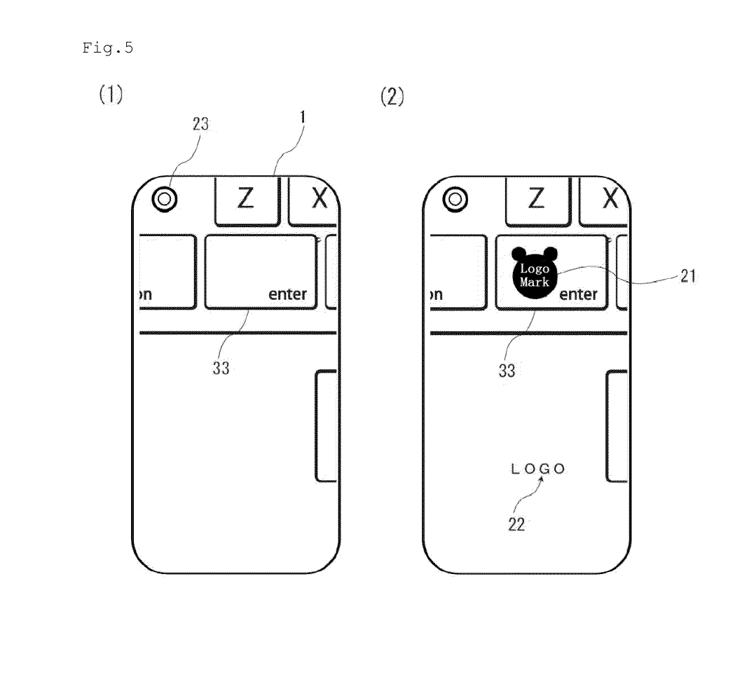

FIG. 5 illustrates decoration applied on the case for a mobile electronic device in Example 3. FIG. 5(1) is a pattern applied on the case 1. FIG. 5(2) illustrates the case attached to the main body of the mobile electronic device 2. If a pattern 33 of a button on a keyboard of a computer on the case 1 is overlapped with the logo mark 21, the logo mark 21 looks like a surface design of an input key of the keyboard. That is, by applying the figure of the keyboard button on the case at a predetermined position and with a predetermined shape or size, a motif of the keyboard button using the logo mark is created for users.

### Embodiment 4

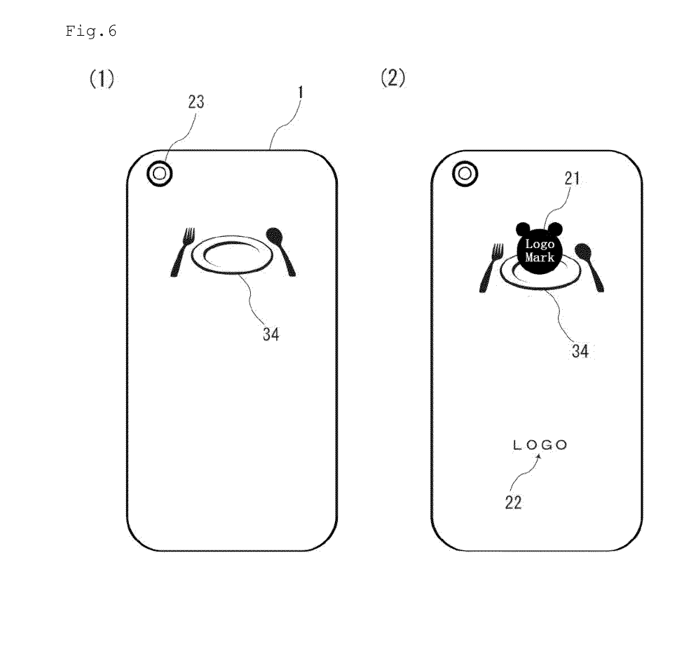

FIG. 6 illustrates decoration applied on the case for a mobile electronic device in Example 4. FIG. 6(1) is a pattern applied on the case 1. FIG. 6(2) illustrates the case attached to the main body of the mobile electronic device 2. If a pattern 34 of a plate with a fork and a spoon placed right and left on the case 1 is overlapped with the logo mark 21, the logo mark 21 appears to be on the plate on the table. That is, by applying the figure of the plate with the fork and the spoon on the case at a predetermined position and with a predetermined shape or size, a motif of eating the logo mark is created for users.

### Embodiment 5

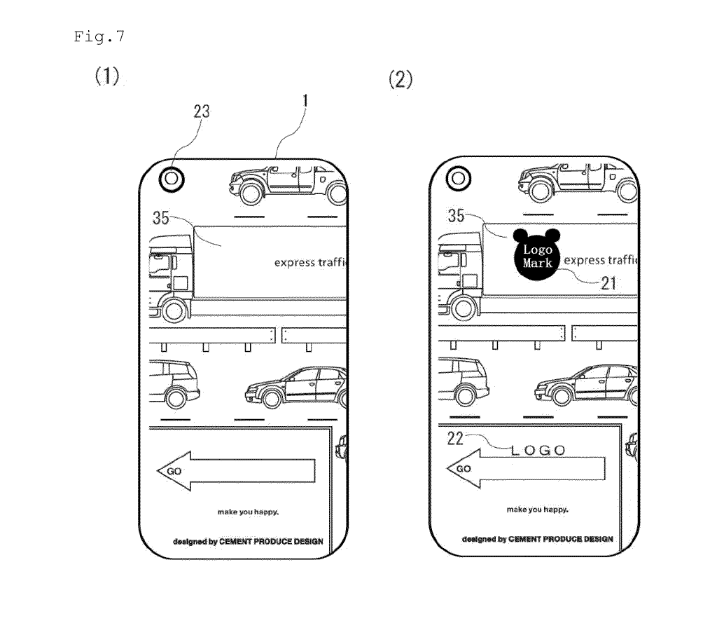

FIG. 7 illustrates decoration applied on the case for a mobile electronic device in Example 5. FIG. 7 (1) is a pattern applied on the case 1. FIG. 7 (2) illustrates the case attached to the main body of the mobile electronic device 2. If a pattern 35 of an automobile or a truck on the case 1 is overlapped with the logo mark 21, the logo mark 21 looks as if it is drawn on the side face of the truck. That is, by applying the figure of the truck on the case at a predetermined position and with a predetermined shape or size, a motif of carrying the logo mark of the mobile electronic device is created for users.

### Embodiment 6

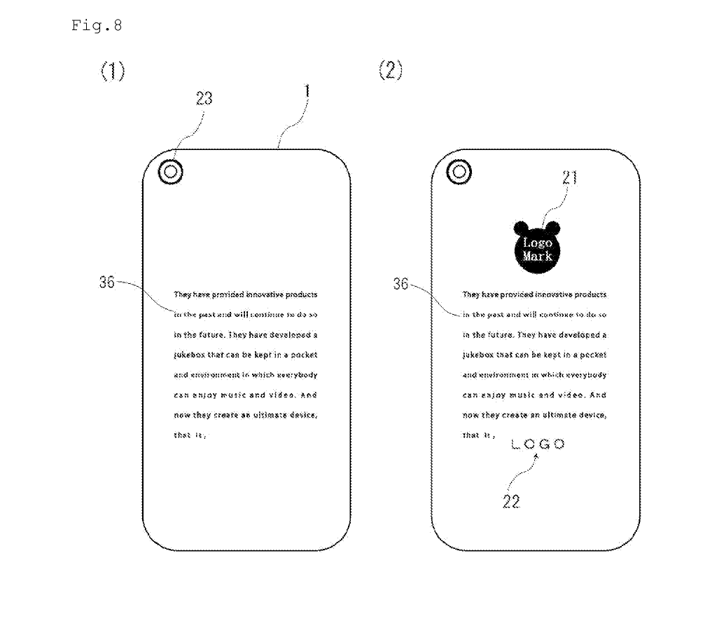

FIG. 8 illustrates decoration applied on the case for a mobile electronic device in Example 6. FIG. 8(1) is a pattern applied on the case 1. FIG. 8(2) illustrates the case attached to the main body of the mobile electronic device 2. If a pattern 35 of characters on the case 1 is overlapped with the logo mark 2.1 and the LOGO 22, the message appears below the logo mark 21, and the LOGO looks as if it is drawn as a part of the message at last. That is, by applying the characters of the case 1 on the case at a predetermined position and with a predetermined shape or size, a motif of the message of the logo mark of the

Mobile electronic device is created for users.

### Embodiment 7

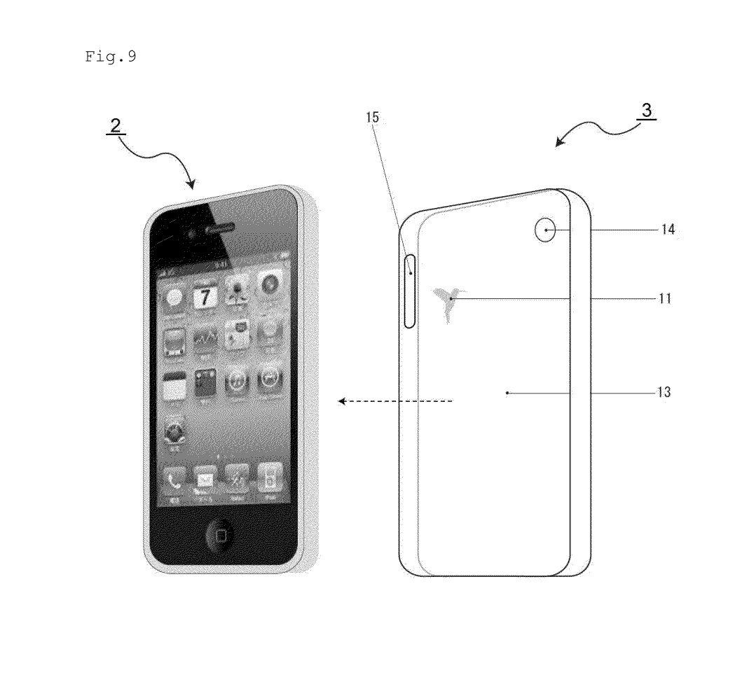

FIG. 9 is an explanatory perspective view of a protective film for a mobile electronic device of the present invention and the mobile electronic device. The front face of the mobile electronic device 2 is a touch-panel mobile phone. A protective film 3 protects a portion from the back face to the side faces of the mobile electronic device 2. The hole 14 for a camera lens corresponding to the lens position of the camera of the mobile electronic device 2 is provided in the back face 13 of the protective film 3. The hole 15 for the operation switch corresponding to the operation switch position of the mobile electronic device 2 is also provided in the protective film 3. The pattern 11 is applied on the back face 13 of the protective film 3 by mirror printing in silver color.

The protective film formed of a resin film having a hard coat layer and an adhesive layer in the hard coat film can be preferably used. The protective film preferably has a total thickness of not more than 150 μm, for example.

The explanations of FIGS. 3 to 8 can be read as explanation for the protective film by replacing the case 1 by the protective film 3.

### INDUSTRIAL APPLICABILITY

The present invention is useful as a case or a protective film for a mobile phone, a mobile digital music player, a mobile computer such as a tablet computer and a laptop computer, a mobile game machine, an electronic dictionary and an electronic. organizer.

### Description of Symbols

1. Case
2. Mobile electronic device
3. Protective film
11. Pattern
12. Frame
13. Back face
14. Hole for a camera lens
15. Hole for an operation switch
21. Logo mark
22. Logo
23. Camera lens

1. A case for a mobile electronic device, having a shape conforming to an outer shape of a back face and side faces of the mobile electronic device, characterized in that:
the case is made of a translucent material; and
figures or characters are applied on the outer surface side or the inner surface side of the case covering the back face of the mobile electronic device so that when the case is attached to the mobile electronic device, a logo mark and a logo character of the device can be seen through, and one motif can be created integrally with at least one of the logo mark and the logo character.

2. The case for a mobile electronic device according to claim 1, wherein
the figures or characters on the case are provided on the outer surface or the inner surface of the case by mirror printing.

3-7. (canceled)

8. The case for a mobile electronic device according to claim 1, wherein
the case is formed of a transparent synthetic resin sheet.

9. The case for a mobile electronic device according to claim 1, wherein
the figure on the case is any one of a vehicle carrying the logo mark of the mobile electronic device, a building having the logo mark of the mobile electronic device as contents of a signboard on the roof, a button of a keyboard using the logo mark of the mobile electronic device, a container or package of the logo mark of the mobile electronic device, and an animal or a plant in contact with the logo mark of the mobile electronic device.

10. The case for a mobile electronic device according to claim 2, wherein
the case is formed of a transparent synthetic resin sheet.

11. The case for a mobile electronic device according to claim 2, wherein
the figure on the case is any one of a vehicle carrying the logo mark of the mobile electronic device, a building having the logo mark of the mobile electronic device as contents of a signboard on the roof, a button of a keyboard using the logo mark of the mobile electronic device, a container or package of the logo mark of the mobile electronic device, and an animal or a plant in contact with the logo mark of the mobile electronic device.

12. A protective film for a mobile electronic device covering an outer shape of a back face and side faces of the mobile electronic device, characterized in that:
the protective film is made of a translucent material; and
figures or characters are applied on the outer surface side or the inner surface side of the protective film covering the back face of the mobile electronic device so that when the protective film is attached to the mobile electronic device, a logo mark and a logo character of the mobile electronic device can be seen through, and one motif can be created integrally with at least one of the logo mark and the logo character.

13. The protective film for a mobile electronic device according to claim 12, wherein
the figures or characters on the protective film are provided on the outer surface or the inner surface of the protective film by mirror printing.

14. The protective film for a mobile electronic device according to claim 12, wherein
the figure on the protective film is any one of a vehicle carrying the logo mark of the mobile electronic device, a building having the logo mark of the mobile electronic device as contents of a signboard on the roof, a button of a keyboard using the logo mark of the mobile electronic device, a container or package of the logo mark of the mobile electronic device, and an animal or a plant in contact with the logo mark of the mobile electronic device.

15. The protective film for a mobile electronic device according to claim 13, wherein
the figure on the protective film is any one of a vehicle carrying the logo mark of the mobile electronic device, a building having the logo mark of the mobile electronic device as contents of a signboard on the roof, a button of a keyboard using the logo mark of the mobile electronic device, a container or package of the logo mark of the mobile electronic device, and an animal or a plant in contact with the logo mark of the mobile electronic device.
